(19) United States
(12) Patent Application Publication
(10) Pub. No.: US 2006/0183029 A1
(43) Pub. Date: Aug. 17, 2006

(54) Method for producing a mask arrangement and use of the mask arrangement

(76) Inventors: Hagen Klauk, Stuttgart (DE); Florian Eder, Erlangen (DE); Marcus Halik, Erlangen (DE); Dirk Rohde, Leipzig (DE); Gunter Schmid, Hemhofen (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/346,572

(22) Filed: Feb. 3, 2006

(30) Foreign Application Priority Data
Feb. 9, 2005 (DE) 10 2005 005 937.6

(51) Int. Cl. G03C 5/00; G03F 1/00

(52) U.S. Cl. 430/5; 430/311; 430/312; 430/313

(57) ABSTRACT

A method is provided for producing a mask arrangement that is used for additive forming of organic semiconductor material regions on a substrate. The mask arrangement is formed by applying a photocrosslinkable polymer material to a mask carrier region, exposing it in a controlled and selective and thereby patterned manner and subsequently developing it. The developing process facilitates the removal of polymer material regions that are not exposed, and have not been photocrosslinked, from surface regions of the mask carrier region such that the desired mask arrangement is produced.

### CROSS REFERENCE TO RELATED APPLICATIONS

This application claims priority under 35 USC § 119 to German Application No. DE 10 2005 005 937.6, filed on Feb. 9, 2005, and titled “Method for Producing a Mask Arrangement and Use of the Mask Arrangement,” the entire contents of which are hereby incorporated by reference.

### FIELD OF THE INVENTION

The present invention relates to a method for producing a mask arrangement and in particular to a method for producing a mask arrangement for the additive forming of organic semiconductor material regions on a substrate. The present invention also relates to a method for fabricating photopatterned stencil masks for the locally defined deposition of organic semiconductor layers.

### BACKGROUND

In the development of modern semiconductor technologies, differing sets of requirements have recently led to the increased use of organic semiconductor materials. There are various methods that can be used for the formation of organic semiconductor material regions or organic semiconductor layers. On the one hand, the subtractive patterning mechanisms already known from silicon technology can in principle be used (albeit in a modified form) for organic semiconductor materials. A disadvantage of subtractive patterning measures is that, once a layer of material has been formed and deposited over the entire surface area, it has to be subjected to a further processing step of patterning. This may have adverse effects on the properties of the organic semiconductor material regions remaining after the patterning step.

Methods known as additive patterning methods have also been developed which obviate the need for subsequent patterning. In particular, in the depositing process for the organic semiconductor material regions, the material to be deposited is already imparted with an appropriate geometry during the depositing process. In other words, additive patterning methods provide selective and patterned depositing on a corresponding surface region.

Such additive depositing of organic semiconductor materials first requires correspondingly patterned masking by providing an appropriate mask arrangement. Previous efforts to form appropriate mask arrangements have been restricted with regard to the spatial and geometrical resolution, since the previously used layer thicknesses of the mask materials used as a basis and the previously used patterning measures (for example laser ablation or laser cutting) have previously precluded higher spatial and geometrical resolution. Thus, at best, edge lengths or geometrical details with a resolution above 20 μm are possible.

### SUMMARY OF THE INVENTION

The present invention provides a method for producing a mask arrangement for the additive forming of organic semiconductor material regions on a substrate with which appropriate mask arrangements with a higher spatial resolution can be produced with great reliability.

In accordane with the present invention, a method for producing a mask arrangement, and in particular for the additive forming of organic semiconductor material regions on a substrate, comprises: providing a mask carrier region with a surface region; applying a polymer material region with or from a photocrosslinkable polymer material on the surface region of the mask carrier region; selectively controlling and patterning an exposure of the photocrosslinkable polymer material of the polymer material region applied to the surface region of the mask carrier region so as to form an exposed pattern in the polymer material region with regions that are exposed and thereby substantially crosslinked with regard to the polymer material and with regions of the polymer material that are unexposed and thereby substantially not crosslinked with regard to the polymer material; and developing the patterned-exposed polymer material region, where the regions of the polymer material region that are exposed and thereby substantially crosslinked with regard to the polymer material remain on the surface region of the mask carrier region and the regions of the polymer material region that are not exposed and thereby substantially not crosslinked with regard to the polymer material are removed from the surface region of the mask carrier region such that a resultant photomask arrangement is formed on the surface region of the mask carrier region.

An important feature of the present invention is producing a mask arrangement for the additive forming of organic semiconductor material regions on a substrate with a particularly high spatial resolution and, at the same time and in a particularly reliable and robust manner, applying a photocrosslinkable polymer material to the surface of an underlying mask carrier region, exposing it in a selectively controlled and consequently patterned manner and, after appropriate exposure, developing it. This allows the necessary structural minimizations within the optical configuration of the exposure process to be achieved with greater reliability and flexibility in comparison to conventional methods.

In one embodiment of the method according to the invention for producing a mask arrangement, a mask carrier region comprises one or more materials selected from the group consisting of a glass, a semiconductor material, silicon, metal foils, thin metal plates and thin sheet-metal plates.

In another embodiment of the method according to the invention for producing a mask arrangement, a planar mask carrier region is provided. In accordance with a preferred embodiment of the invention for producing a mask arrangement, a mask carrier region with a planar surface region is provided.

In another preferred embodiment of the method according to the invention for producing a mask arrangement, an organic photocrosslinkable polymer material is provided. More preferably, a UV-sensitive photocrosslinkable polymer material is provided.

In an alternative embodiment of the method according to the invention for producing a mask arrangement, a photocrosslinkable polyimide is provided as the photocrosslinkable polymer material. In yet another alternative embodiment, a photocrosslinkable polybenzoxazole is provided as the photocrosslinkable polymer material.

The method step of applying the photocrosslinkable polymer material can be performed by a process or combination of processes selected from the group consisting of applying the photocrosslinkable polymer material by spin coating, applying the photocrosslinkable polymer material by spraying, applying the photocrosslinkable polymer material by doctor blading and applying the photocrosslinkable polymer material by lamination via a film containing the photocrosslinkable polymer material.

In addition, the method step of exposing the photocrosslinkable polymer material can be performed using UV radiation.

The method step of exposing the photocrosslinkable polymer material can also be performed using a photomask.

In still another embodiment of the invention, the method step of exposing the polymer material region can be performed by selective exposure of the polymer material region. In the method step of exposing the crosslinkable polymer material, regions that are exposed and thereby crosslinked with regard to the polymer material are preferably produced by selective exposure.

Alternatively, in the method step of exposing the polymer material region, polymer material regions that are not crosslinked with regard to the polymer material are produced by selective non-exposure or shadowing of the exposure.

In another embodiment of the invention, in the step of developing the patterned-exposed polymer material and the polymer material region, the polymer material regions that are not exposed and consequently not crosslinked with regard to the polymer material can be removed from the surface region of the mask carrier region by application of a solvent.

In addition, after completion of the method step of developing the patterned-exposed polymer material and the polymer material region, a further step is provided of curing (e.g., thermally curing) the mask arrangement obtained.

To make handling more stable and easier, the actual mask arrangement obtained may be clamped on a fixed frame or be formed by such a fixed frame.

A method for producing a semiconductor component, in particular on the basis of an organic semiconductor material, is also provided in accordance with the present invention. In this method, the organic semiconductor material is additively applied to a substrate by a mask pattern, where the mask pattern has been produced by the method according to the invention for producing a mask arrangement.

The fabrication of photo-patterned stencil masks for the locally defined deposition of organic semiconductor layers is also provided in accordance with the present invention.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIGS. 1-6 schematically depict cross-sectional side views of beginning, intermediate and final stages of a mask arrangement which illustrate a method of forming the mask arrangement to facilitate additive forming of organic semiconductor material regions in accordance with the present invention.

FIGS. 7-9 schematically depict cross-sectional side views of a substrate with the mask arrangement depicted in FIG. 6 and which illustrate a method of additive forming of organic semiconductor material regions on the substrate and with the mask arrangement in accordance with the present invention.

FIG. 10 depicts a plan view of a polyimide stencil mask produced in accordance with the present invention.

FIG. 11 depicts a plan view of a pentazene transistor that has been produced using a mask arrangement in accordance with the present invention.

FIG. 12 is a graph showing output characteristics for the pentazene transistor of FIG. 11.

FIG. 13 depicts a plan view of a NAND gate with five pentazeile transistors and that has been produced using a mask arrangement and with organic semiconductor regions in accordance with the present invention.

FIG. 14 is a graph showing transmission characteristics of the NAND gate of FIG. 13.

### DETAILED DESCRIPTION

The formation of integrated circuits and flat sensors and screens on the basis of organic semiconductor layers typically requires the patterning of the organic semiconductor layer or the organic semiconductor layers in order to reduce in a specific manner the leakage currents occurring between the individual components (e.g., transistors, light-emitting diodes or sensors) or between neighboring interconnects. In principle, the patterning of the organic semiconductor layer may be performed by subtractive patterning methods after the layer has been deposited over the full surface area. An example of a substractive patterning method is spin-coating a photopatternable etching mask (e.g., with or without a photo resist) on the semiconductor layer and subsequent removal of the semiconductor material in the non-masked regions (e.g., by etching in a plasma).

However, many of the organic semiconductor materials used for obtaining high-grade organic components are extremely sensitive to the deposition of subsequent layers, particularly when the deposition of the subsequent layers includes the use of organic or polar solvents. In conventional methods, a certain degradation of the electrical properties of the organic components as a consequence of the subtractive patterning of the organic semiconductor layers is consciously accepted.

An alternative to subtractive patterning (which is always necessary when the organic semiconductor layer is deposited on the substrate over its full surface area) is the selectively and locally defined deposition of the organic semiconductor layer, which is also referred to as additive patterning. In this case, the organic molecules are selectively deposited on the substrate only where they are required for the electronic functionality of the components. Subsequent subtractive patterning of the organic semiconductor layer is not necessary, and there is no need for an etching mask to be deposited on the organic semiconductor layer and degradation of the organic semiconductor layer is specifically avoided.

In the case of polymeric organic semiconductor materials, which are preferably applied from organic solvents, a series of printing processes, such as inkjet printing and gravure printing, are suitable in particular for the local deposition.

By contrast, the deposition of low molecular weight organic compounds, such as pentazene (which is preferably used for the production of organic transistors) and Alq3 (which is used for the production of organic light-emitting diodes) is generally performed from the gas phase (i.e., by vapor-depositing processes). For the patterned deposition of low molecular weight compounds from the gas phase, the use of so-called stencil or shadow masks is suitable in principle. These are masks which are provided with holes through which the organic semiconductor material is vapor-deposited locally onto the surface of the substrate. The mask is brought into contact with the substrate, mechanically fixed there, and after the deposition of the organic semiconductor layer, is removed again from the substrate without any of it remaining behind.

One requirement for producing the stencil masks is providing a sufficiently thin and sufficiently robust material (for example, cold-rolled high-grade steel foils or flexible polyimide films, in each case with a thickness of about 20 μm to 150 μm) and a method for defining the holes in the mask in a manner that corresponds precisely to the pattern. At present, the holes are usually produced using a laser. Laser cutting or laser ablation allows structures with an edge length of about 20 μm to be cut out; smaller structures cannot be defined if a laser is used (see, for example, Dawn Muyres et al., “Polymeric aperture masks for high-performance organic integrated circuits”, Journal of Vacuum Science and Technology A, vol. 22, no. 4, pp. 1892 1895, July/August 2004).

In accordance with the present invention, a method is provided which, by using a photopatternable polyimide (PI) or a photopatternable polybenzoxazole (PBO), makes it possible to produce stencil masks with much better pattern resolution (about 2 μm).

The stencil masks are produced from photocrosslinkable polyimide (PI) or from photocrosslinkable polybenzoxazole (PBO). A layer of photocrosslinkable polyimide is applied by spin coating to a solid, level substrate (for example, a sheet of glass or silicone). Photocrosslinkable polyimides are commercially available. The layer thickness of the polyimide can be set over a wide range, from about 1 μm to about 100 μm, by the concentration of the polyimide in the solvent and by the choice of the process parameters during the spin coating. A layer thickness is chosen which is greater than the smallest size of structure to be replicated by no more than a factor of about 5 to 10. If, for example, the stencil mask is to be used to replicate structures with an edge length of about 2 μm, a polyimide layer thickness of, for example, about 10 μm to 20 μm should be set. Once the polyimide layer has dried, the substrate is exposed with ultraviolet radiation through the photomask. This causes a chemical reaction in the polyimide in the exposed regions, leading to crosslinkage of the polyimide. The substrate is subsequently developed in a suitable developer solution; the regions of the polyimide that are not exposed (and therefore not crosslinked) are dissolved without anything remaining behind, that is to say they are removed from the substrate. The exposed regions withstand the developer solution thanks to the chemical crosslinkage that has taken place there and they remain on the substrate.

Following the developing and thermal curing of the layer, the polyimide film is removed from the substrate. The result is that a polyimide film with completely opened holes is obtained. This film may be used as a stencil mask for the local gas-phase deposition of organic semiconductor materials in the production of electronic components. The film is expediently clamped on a fixed frame.

The invention provides a method for producing stencil masks from photopatterned polyimide film. In comparison with stencil masks that are produced by a laser method, the use of a photopatterned polyimide film allows the resolution of much smaller structures.

An example of the production of a stencil mask according to the invention is schematically described as follows. An about 10 nm thick layer of titanium is produced on a silicon substrate by cathode sputtering, making it easier for the polyimide mask to be detached later from the silicon substrate. An about 20 μm thick layer of Probimide 7510, a photopatternable polyimide from Arch Chemicals, is applied by spin coating at a spinning speed of about 1000 revolutions per minute to the silicon substrate, coated over its entire surface area with titanium. The substrate is placed onto a hot plate at a temperature of about 100° C. for about 3 minutes or into a vacuum oven at a temperature of about 100° C. for about 10 minutes, in order to drive out the solvent and dry the polyimide layer.

On a commercially available exposure device, the polyimide layer is exposed to monochromatic light at a wavelength of about 365 nm of an exposure dose of about 250 mJ/cm² through a glass mask provided with chromium structures; depending on the intensity of the light, the exposure lasts from several seconds to several minutes.

The substrate is placed in a bath with the commercially available developer solution HTR-D2; in this case, the polyimide regions that are not exposed, that is to say not crosslinked, are detached (that is to say removed from the substrate), while the regions that are crosslinked by the exposure remain on the substrate. Consequently, holes are produced in the polyimide layer by the developing process.

The polyimide layer is cured in a vacuum oven at a temperature of about 350° C. The substrate is placed into an about 5% solution of hydrofluoric acid in water. The action of the hydrofluoric acid causes the titanium to be etched, whereby the polymer film is gently detached from the silicon substrate. The film is removed from the hydrofluoric acid solution and adhesively attached onto a thin metal frame. The sensor mask is now ready for use.

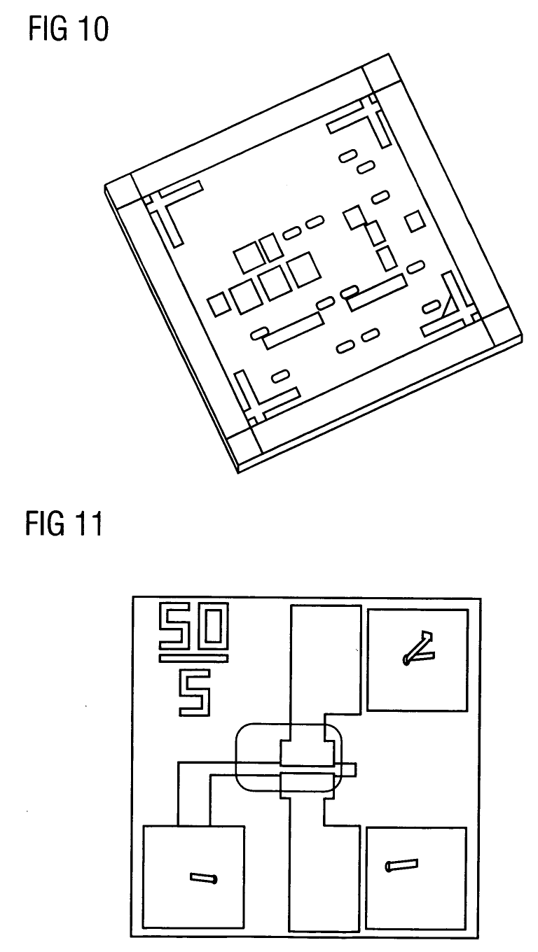

FIG. 10 is shows a polyimide stencil mask fabricated according to the invention and which is about 20 μm thick, fastened on a fixed frame of extruded aluminum.

An example is now provided showing the production of field-effect transistors and integrated circuits on the basis of low molecular weight organic semiconductors (e.g., pentazene) using a stencil mask of photopatterned polyimide according to the present invention. An about 20 nm thick layer of aluminum is vapor-deposited onto a glass substrate; this layer of aluminum is patterned by photolithography and wet-chemical etching, in order to define the gate electrodes of the transistors. Subsequently, an about 100 nm thick layer of polyvinyl phenol is applied by spin coating to provide the gate dielectric.

Vapor-deposited over the polyvinyl phenol layer is an about 30 nm thick layer of gold, which is patterned by photolithography and wet-chemical etching, in order to produce the source and drain contacts of the transistors.

A stencil mask formed in a manner as described above is placed onto the substrate, adjusted with the aid of suitable registration marks, and fixed on the substrate by a mechanical clamping device. An about 30 nm thick layer of the organic semiconductor pentazene is vapor-deposited onto the substrate. The substrate surface is wetted with the pentazene exclusively in the region of the holes defined in the stencil mask. The stencil mask is subsequently removed from the substrate.

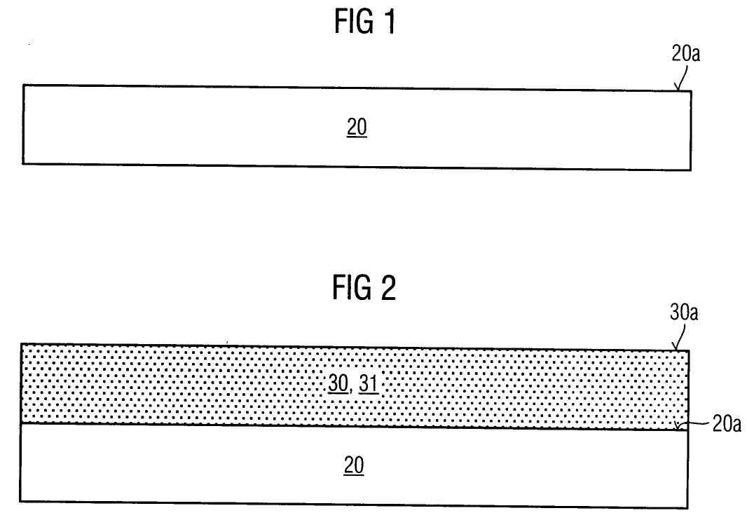

An exemplary method for forming a mask arrangement such as is depicted in FIG. 10, and in particular a mask arrangement useful for the additive forming of organic semiconductor material regions on a substrate, is described with reference to FIGS. 1 to 6.

Referring to FIG. 1, a mask carrier substrate 20 in planar form is provided with a surface region 20a. In the transition to the intermediate state that is shown in FIG. 2, a material region 30 of a photocrosslinkable polymer material 31 is then formed on the planar surface region 20a. This can be achieved, for example, by spin coating. Applying the material region 30 has the effect of producing the corresponding surface region 30a.

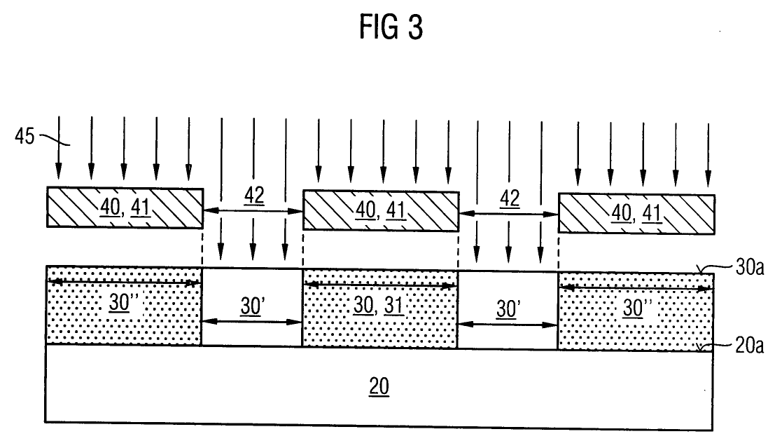

In the transition to the intermediate state that is represented in FIG. 3, a photomask 40 is then arranged above the surface region 30a, and at a distance from it, with corresponding mask elements 41 and apertures 42. The photomask 40 is correspondingly subjected to radiation 45, for example UV radiation, to be precise in such a way that, by casting an appropriate shadow in or on the material region 30, corresponding irradiated or exposed regions 30′ and non-irradiated or unexposed regions 30″ are produced in or on the material region 30 of the photocrosslinkable polymer material 31, the unexposed material regions 30″ of the material region 30 corresponding to the corresponding mask elements 41 and the exposed material regions 30′ of the material region 30 corresponding to the apertures 42 in the photomask 40. In this way, the radiation or exposure produces in or on the material region 30 an appropriate exposure structure with exposed regions 30′ and with unexposed regions 30″, the nature of the photocrosslinkable polymer material 31 used as a basis meaning that after the exposure there is a corresponding crosslinkage in the exposed regions 30′ that is absent in the unexposed regions 30″ of the polymer material region 30.

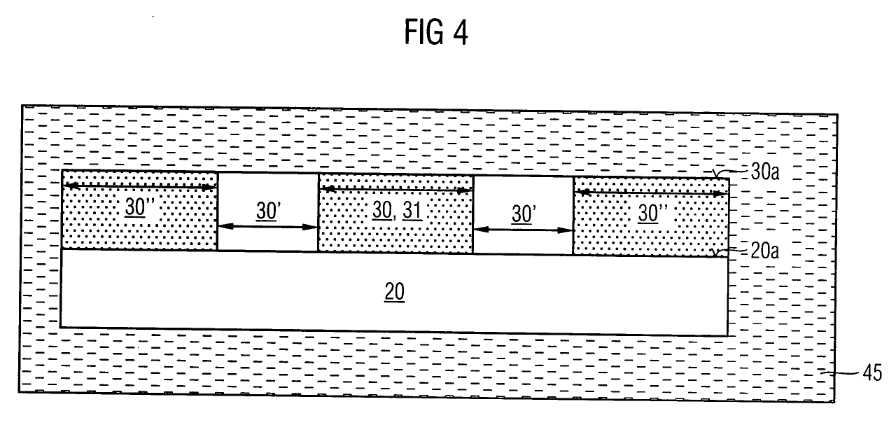

In the transition to the intermediate state that is shown in FIG. 4, the patterned-exposed arrangement according to FIG. 3 is introduced into an appropriate solvent 45 or is at least treated with the solvent on the surface 30a. As a result, the unexposed material regions 30″ of the polymer material 31 used as a basis, which are not crosslinked, are dissolved and consequently removed from the surface 20a of the underlying mask carrier region 20, so that the exposed and crosslinked polymer material regions 30′ exclusively remain, the entirety of which then forms the corresponding mask arrangement 10.

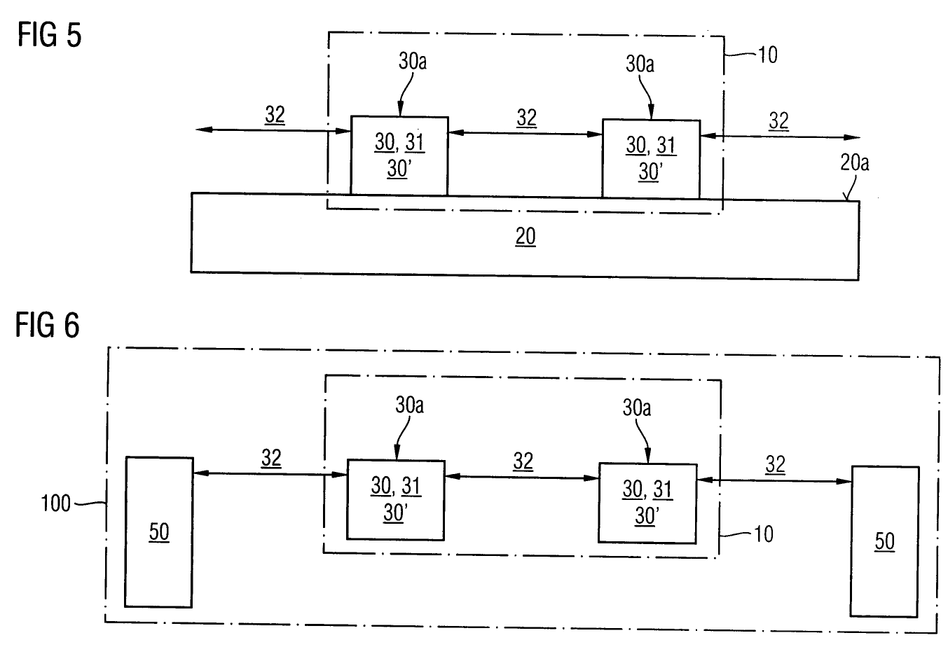

In the transition to the intermediate state that is represented in FIG. 6, the mask arrangement 10 is then removed from the surface region 20a of the mask carrier region 20 and clamped in a frame 50, which makes handling of the corresponding mask arrangement 10 easier and gentler. In this way, the mask 100 for depositing organic semiconductor materials 91 on a substrate 80 is produced.

FIGS. 7 to 9 likewise show in a schematic and sectioned side view the use of the mask arrangement 10 clamped in the frame 50 according to FIG. 6 in the method for the additive forming of organic semiconductor regions on a substrate 80.

In the intermediate state according to FIG. 7, the mask arrangement 10 secured in the frame 50 is applied to an underlying substrate 80 with a planar surface region 80a.

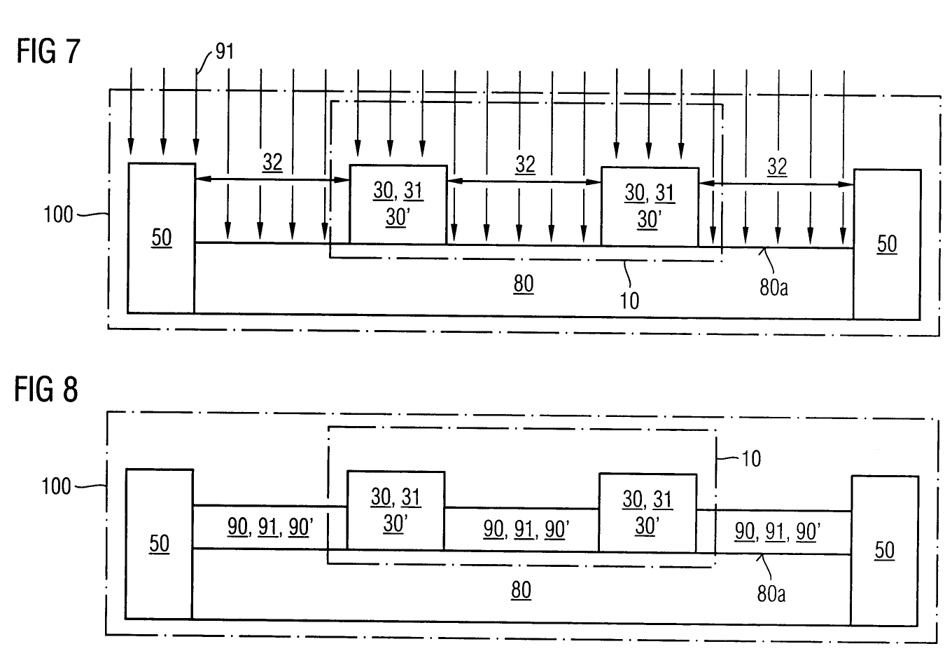

In the transition to the intermediate state that is represented in FIG. 8, an organic semiconductor material 91 is then deposited according to the arrows shown in FIG. 7, this material being deposited on the surface region 80a of the substrate 80 exclusively between the mask regions 30′ of the mask arrangement 10, that is to say in the apertures or intermediate spaces 32, where it forms an organic semiconductor material region 90 of a plurality of individual regions 90′ of organic semiconductor material, because there is no corresponding shadowing of the surface region 80a by the mask region 10 because of the mask apertures 32.

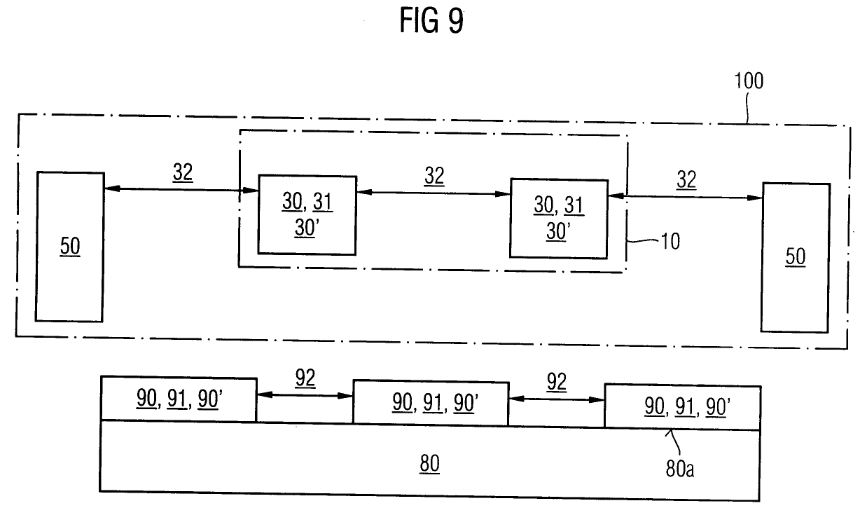

Removal of the mask 100, which includes the mask arrangement 10 and the frame 50, from the surface region 80a of the underlying substrate 80 is shown in FIG. 9. After removal of mask 100, the corresponding individual regions 90′ with the organic semiconductor material 91 remain in a patterned way on the substrate surface region 80a as the organic semiconductor material region 90 with corresponding apertures 92, without an additional patterning step being required after the depositing.

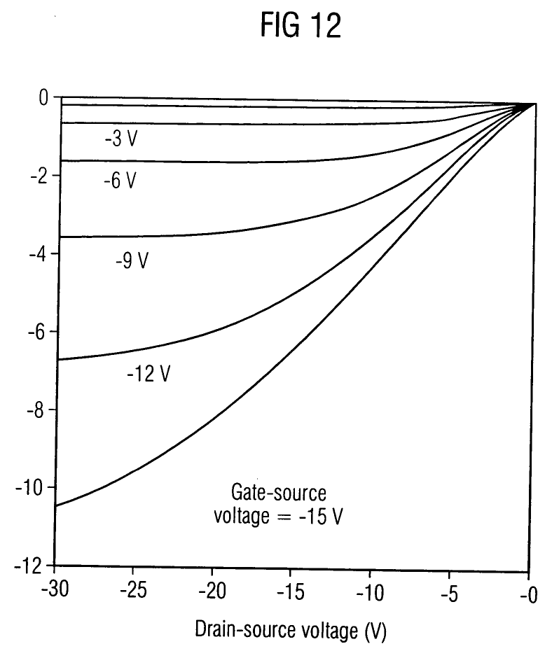

FIGS. 11 and 12 show a pentazene transistor and a graph illustrating output characteristics of the pentazene transistor, in the production of which the pentazene layer was produced using a polyimide mask fabricated according to the invention.

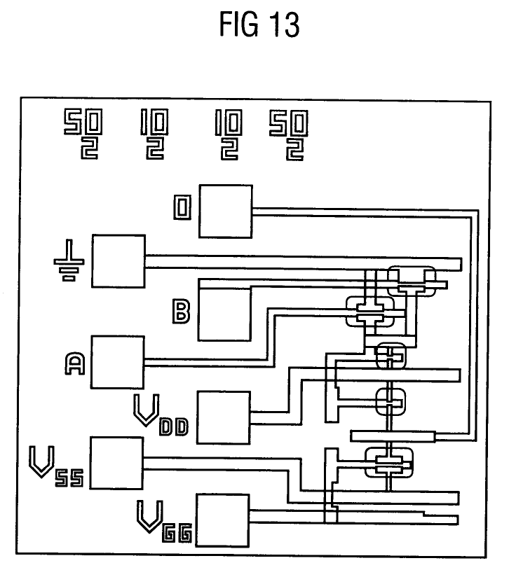

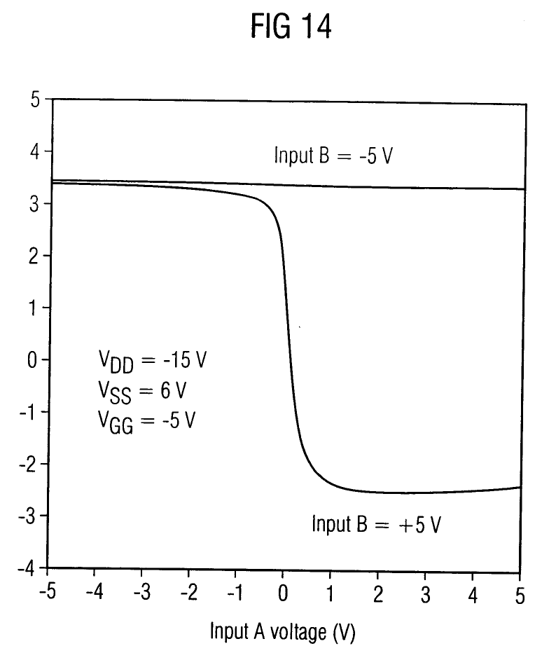

FIGS. 13 and 14 show a NAND gate and a graph illustrating transmission characteristics of the NAND gate. The NAND gate of FIG. 13 includes five pentazene transistors that have been formed by a pentazene layer, where the pentazene layer has been formed and patterned using a mask arrangement formed in accordance with the present invention.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF DESIGNATIONS

10 mask arrangement
20 mask carrier region
20a surface region
30 polymer material region
30′ exposed/crosslinked material region/polymer material region
30″ unexposed/not crosslinked material region/polymer material region
31 polymer material
32 aperture, gap, intermediate space
40 photomask pattern, photomask
41 mask material for photomask, photomask element
42 photomask aperture, aperture, gap, intermediate space
45 radiation, light, UV radiation
48 solvent, developing medium, developer
50 frame
80 substrate
80a surface region
90 organic semiconductor material region, layer of organic semiconductor material
90′ individual region of the organic semiconductor material
91 organic semiconductor material
92 aperture, gap, intermediate space
100 mask

What is claimed:

1. A method for producing a mask arrangement used for the additive forming of organic semiconductor material regions on a substrate, the method comprising:
providing a mask carrier region with a surface region;
applying a polymer material region comprising a photocrosslinkable polymer material on the surface region of the mask carrier region;
providing a selective patterned exposure of the polymer material region applied to the surface region of the mask carrier region to expose selected regions of the polymer material region while other regions of the polymer material region are not exposed;
forming different regions within the polymer material region that are based upon the selective patterned exposure, the different formed regions including exposed regions with polymer material that is substantially crosslinked and unexposed regions with polymer material that is substantially not crosslinked; and
developing the polymer material region with different formed regions such that the exposed regions with polymer material that is substantially crosslinked remain on the surface region of the mask carrier region and the unexposed regions with polymer material that is substantially not crosslinked are removed from the surface region of the mask carrier region;
wherein the mask arrangement is formed on the surface region of the mask carrier region after development of the polymer material region with different formed regions.

2. The method of claim 1, wherein the mask carrier region comprises at least one material selected from the group consisting of a glass, a semiconductor material, silicon, metal foils, thin metal plates and thin sheet-metal plates.

3. The method of claim 1, wherein the mask carrier region is planar.

4. The method of claim 1, wherein the surface region of the mask carrier region is planar.

5. The method of claim 1, wherein the photocrosslinkable polymer material is organic.

6. The method of claim 1, wherein the photocrosslinkable polymer material is UV-sensitive.

7. The method of claim 1, wherein the the photocrosslinkable polymer material comprises a photocrosslinkable polyimide.

8. The method of claim 1, wherein the the photocrosslinkable polymer material comprises a photocrosslinkable polybenzoxazole.

9. The method of claim 1, wherein the application of the polymer material region comprising the photocrosslinkable polymer material is performed by at least one of spin coating, spraying, doctor blading and lamination with a film containing the photocrosslinkable polymer material.

10. The method of claim 1, wherein the formation of different regions within the polymer material region is performed using UV radiation.

11. The method of claim 1, wherein the formation of different regions within the polymer material region is performed using a photomask.

12. The method of claim 1, wherein the development of the polymer material region with different formed regions comprises removing the unexposed regions with polymer material that is substantially not crosslinked from the surface region of the mask carrier region by applying a solvent.

13. The method of claim 1, further comprising:
after the development of the polymer material region with different formed regions, curing the formed mask arrangement.

14. The method of claim 1, further comprising:
clamping the formed mask arrangement onto a fixed frame.

15. The method of claim 1, further comprising:
forming a semiconductor component with an organic semiconductor material, wherein the organic semiconductor material is additively applied to a substrate of the semiconductor component using the formed mask arrangement.
